(19) United States
(12) Patent Application Publication
(10) Pub. No.: US 2011/0111135 A1
(43) Pub. Date: May 12, 2011

(54) THIN FILM MANUFACTURING METHOD AND SILICON MATERIAL THAT CAN BE USED WITH SAID METHOD

(76) Inventors: Yuma Kamiyama, Kyoto (JP); Kazuyoshi Honda, Osaka (JP); Yasuharu Shinokawa, Osaka (JP)

(21) Appl. No.: 13/002,876

(22) PCT Filed: Jul. 7, 2009
(86) PCT No.: PCT/JP2009/003163

§ 371 Date: Jan. 6, 2011

(30) Foreign Application Priority Data
Jul. 7, 2008 (JP) 2008-176547

(51) Int. Cl. B05D 5/12; C01B 33/02; B05D 3/06; B05D 3/00; C23C 16/00

(52) U.S. Cl. 427/567; 423/348; 427/568; 427/78; 427/248.1

(57) ABSTRACT

Particles coming from an evaporation source 9 are deposited on a substrate 21 at a predetermined film forming position 33 in a vacuum so as to form a thin film on the substrate 21. A bulk material 32 containing a source material of the thin film is melted above the evaporation source 9, and the melted material is supplied to the evaporation source 9 in the form of droplets 14. A silicon material 32 including a plurality of pores therein is used as the bulk material 32. Preferably, the pores have a lower average internal pressure than an atmospheric pressure. More preferably, the average internal pressure is 0.1 atm or less.

### TECHNICAL FIELD

The present invention relates to a thin film manufacturing method and a silicon material that can be used with the method.

### BACKGROUND ART

Thin film techniques have been used widely to enhance the performance of devices and to reduce the size thereof. Thinned devices not only provide direct benefits to users but also play an important role in environmental aspects such as protection of earth resources and reduction in power consumption.

The advancement of the thin film techniques requires to meet demands such as high efficiency, stabilization, high productivity, and low costs in manufacturing the thin films. For example, long-time film formation techniques are essential to increase the productivity of thin films. For example, when manufacturing a thin film by a vacuum vapor deposition process, it is effective to supply a material to an evaporation source in the long-time film formation.

To supply the material to the evaporation source, various methods can be used in accordance with the material to be used, film forming conditions, etc. Specifically, the following methods are known. (i) A method in which a material in various forms, such as powder, granule, and pellet, is added into the evaporation source. (ii) A method in which a rod-shaped or linear material is immersed in the evaporation source. (iii) A method in which a liquid material is poured into the evaporation source.

The temperature of the evaporation source varies in accordance with the addition of the material into the evaporation source. The change in the evaporation source temperature causes a change in the evaporation rate of the material, that is, a change in the film forming rate. Thus, it is important to minimize the change in the evaporation source temperature. For example, JP 62 (1987)-177174 A discloses a technique in which a material is once melted above a crucible, and then the melted material is supplied to the crucible. Also, there is a method in which a bulk material is melted continuously from its tip above a crucible, and the droplets generated by the melting are supplied to the evaporation source.

### CITATION LIST

### Patent Literature

PTL 1: JP 62 (1987)-177174 A

### SUMMARY OF INVENTION

### Technical Problem

The method of supplying a material in the form of droplets is advantageous in that the thermal influence on the evaporation source is small. However, this method requires to drop the droplets exactly into the evaporation source. Therefore, it is necessary to specify the heating range for the rod-shaped material as well as to perform rapid heating so as to control the starting point of melting the rod-shaped material.

However, in the case of using a brittle material, such as silicon, there is a possibility that the thermal expansion during the rapid heating crushes the rod-shaped material and the unmelted material falls into the crucible. When the unmelted material falls into the crucible, it absorbs the heat and lowers the temperature of the material (the melt) in the crucible, and consequently lowers the evaporation rate of the material evaporating from the crucible.

In some cases, the thermal expansion during the rapid heating crushes the rod-shaped material and fine powder is generated. The fine powder scatters as so-called splashes, and is deposited on a substrate or causes damage to the substrate. Particularly, in a method in which the material in the crucible is heated with an electron beam, the occurrence of splashes becomes significant. This is because the electron beam makes it easy for the fine powder to be electrically charged, and the fine powder is more likely to scatter because of the electrostatic repulsion among the powder particles. Furthermore, the occurrence of splashes accelerates the deposition of the material on an inner wall and a shielding plate of a vacuum chamber, which is also a problem. In this circumstance, there is needed a method that enables to supply stably the material to the evaporation source, with a minimum of splashes being generated.

More specifically, the present invention provides a method for manufacturing a thin film, including the steps of

depositing particles coming from an evaporation source on a substrate at a predetermined film forming position in a vacuum so as to form the thin film on the substrate; and

melting a bulk material containing a source material of the thin film above the evaporation source and supplying the melted material to the evaporation source in the form of droplets.

A silicon material including a plurality of pores therein is used as the bulk material.

In another aspect, the present invention is a method for manufacturing a negative electrode for a lithium ion secondary battery, including the step of depositing silicon as a negative electrode active material capable of occluding and releasing lithium therein and therefrom, on the substrate serving as a negative electrode collector, by the above-mentioned thin film manufacturing method.

In still another aspect, the present invention provides a silicon material as a bulk material that can be used suitably in the above-mentioned method.

### ADVANTAGEOUS EFFECTS OF INVENTION

In the method of the present invention, the silicon material including the pores therein is used as the bulk material. When such a silicon material is used, the pores stop cracks spreading even if the cracks occur due to the thermal expansion during the rapid heating, preventing the silicon material from being crushed. Thus, it is possible to suppress a decrease in the temperature of the melt in the crucible caused by the fall of the crushed material into the crucible, and to suppress a decrease in the evaporation rate that may occur in association with this temperature decrease. Furthermore, it is possible to suppress the splashes generated by the crushing. More specifically, it is possible to prevent fine powder from being generated from the crushing, and as a result, it is possible to prevent the fine powder from being deposited on the substrate and prevent the substrate from being damaged by the fine powder.

### BRIEF DESCRIPTION OF DRAWINGS

FIG. 1 is a schematic view of a thin film manufacturing apparatus to perform a thin film manufacturing method according to one embodiment of the present invention.

FIG. 2 is a schematic top view of an evaporation source in the thin film manufacturing apparatus shown in FIG. 1.

FIG. 3 is a cross-sectional image of a silicon material having pores, captured by X-ray CT scan.

FIG. 4 is a graph showing relationships among the pouring rate of a melt into a mold, the average internal pressure of the pores, and the average nitrogen partial pressure in the pores.

FIG. 5 is a graph showing a relationship between the average internal pressure of the pores and the number of splashes generated.

FIG. 6 is a graph showing a relationship between the average internal pressure of the pores and the occurrence rate of crushing.

FIG. 7 is a graph showing a relationship between the average volume of the pores and the occurrence rate of crushing.

### DESCRIPTION OF EMBODIMENTS

Hereinafter, one embodiment of the present invention will be described with reference to the drawings.

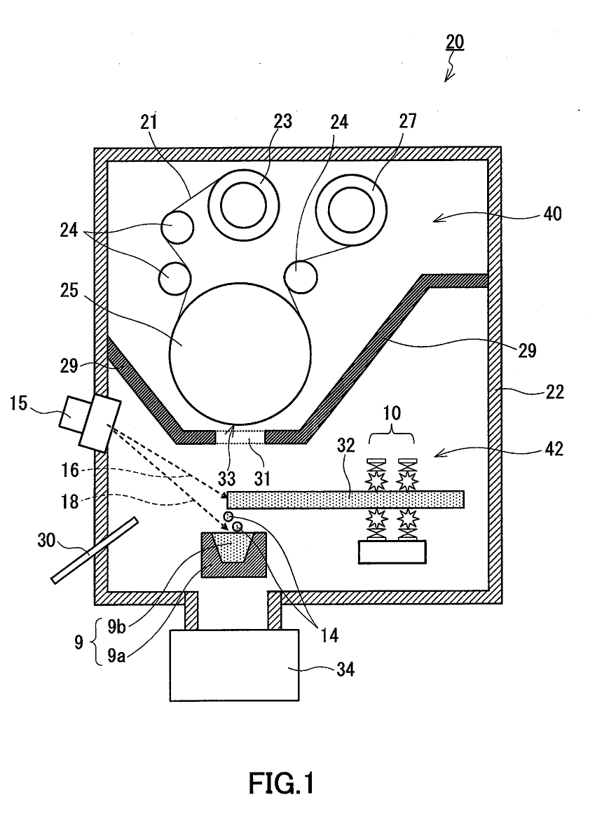

As shown in FIG. 1, a thin film manufacturing apparatus 20 includes a vacuum chamber 22, a substrate transfer unit 40, a shielding plate 29, an evaporation source 9, and a material supplying unit 42. The substrate transfer unit 40, the shielding plate 29, the evaporation source 9, and the material supplying unit 42 are disposed in the vacuum chamber 22. A vacuum pump 34 is connected to the vacuum chamber 22. An electron gun 15 and a source gas inlet 30 are provided on a side wall of the vacuum chamber 22.

The shielding plate 29 partitions the internal space of the vacuum chamber 22 into a first space (a lower space) in which the evaporation source 9 is disposed, and a second space (an upper space) in which the substrate transfer unit 40 is disposed. The shielding plate 29 has an opening 31, through which evaporated particles from the evaporation source 9 can travel from the first space to the second space.

The substrate transfer unit 40 has a function of feeding a substrate 21 to a predetermined film forming position 33 that faces the evaporation source 9, and a function of retracting, from the film forming position 33, the substrate 21 on which a film has been formed. The film forming position 33 is a position on the transfer path for the substrate 21, and also is a position defined by the opening 31 of the shielding plate 29. When the substrate 21 passes through this film forming position 33, the evaporated particles coming from the evaporation source 9 are deposited on the substrate 21. Thus, a thin film is formed on the substrate 21.

Specifically, the substrate transfer unit 40 is composed of a feed roller 23, transfer rollers 24, a cooling can 25, and a take-up roller 27. The substrate on which a film is to be formed is put on the feed roller 23. The transfer rollers 24 are disposed respectively on the upstream side and the downstream side of the transfer direction of the substrate 21. The transfer rollers 24 on the upstream side guide the substrate 21 fed from the feed roller 23 to the cooling can 25. The cooling can 25 supports and guides the substrate 21 to the film forming position 33, and then guides the substrate 21, on which the film has been formed, to the transfer roller 24 on the downstream side. The cooling can 25 has a circular cylindrical shape and is cooled with a refrigerant such as cooling water. The substrate 21 travels along the peripheral surface of the cooling can 25, and is cooled by the cooling can 25 from a side opposite to a side facing the evaporation source 9. The transfer roller 24 on the downstream side guides the substrate 21, on which the film has been formed, to the take-up roller 27. The take-up roller 27 is driven by a motor (not shown), and takes up and holds the substrate 21 on which the thin film has been formed.

During the film formation process, the operation of feeding the substrate 21 from the feed roller 23 and the operation of taking up the substrate 21, on which the film has been formed, along the take-up roller 27 are performed in synchronization with each other. The substrate 21 fed from the feed roller 23 is transferred to the take-up roller 27 through the film forming position 33. That is, the thin film manufacturing apparatus 20 is a so-called take-up thin film manufacturing apparatus for forming a thin film on the substrate 21 that is being transferred from the feed roller 23 toward the take-up roller 27. When such a take-up thin film manufacturing apparatus is used, high productivity can be expected because long-time film formation can be performed. A part of the substrate transfer units 40, such as a motor, may be disposed outside the vacuum chamber 22. In this case, the driving force generated by the motor can be supplied to the various rolls in the vacuum chamber 22 via a rotation introduction terminal.

In the present embodiment, the substrate 21 is an elongated substrate having flexibility. The material of the substrate 21 is not particularly limited. A polymer film or a metal foil can be used. Examples of the polymer film include a polyethylene terephthalate film, a polyethylene naphthalate film, a polyamide film, and a polyimide film. Examples of the metal foil include an aluminum foil, a copper foil, a nickel foil, a titanium foil, and a stainless steel foil. A composite of a polymer film and a metal foil also can be used for the substrate 21.

The dimensions of the substrate 21 are not particularly limited, either, because they are determined according to the type of the thin film to be manufactured and the production volume of the film. The substrate 21 has a width of, for example, 50 to 1000 mm, and a thickness of, for example, 3 to 150 μm.

During the film formation process, the substrate 21 is transferred at a constant speed. The transfer speed is, for example, 0.1 to 500 m/min, although it varies depending on the type of the thin film to be manufactured and the film forming conditions. The film forming rate is, for example, 1 to 50 μm/min. An appropriate tension is applied to the substrate 21 that is being transferred, depending on the material of the substrate 21, the dimensions of the substrate 21, the film forming conditions, etc. The substrate 21 may be transferred intermittently to form a thin film on the substrate 21 in resting state.

The evaporation source 9 is configured so as to heat a material 9b in a crucible 9a with an electron beam 18 emitted from the electron gun 15. That is, the thin film manufacturing apparatus 20 according to the present embodiment is configured as a vacuum vapor deposition apparatus. The evaporation source 9 is disposed in a lower part of the vacuum chamber 22 so that the evaporated material travels vertically upward. Instead of the electron beam, other techniques such as resistance heating and induction heating may be used to heat the material 9b in the crucible 9a.

The opening of the crucible 9a is, for example, circular, oval, rectangular, or toroidal in shape. During a continuous vacuum vapor deposition process, it is effective for the uniformity of the widthwise film thickness to use the crucible 9a having a rectangular opening wider than the width of the film to be formed. As the material of the crucible 9a, metal, an oxide, a refractory material, or the like can be used. Examples of the metal include copper, molybdenum, tantalum, tungsten, and an alloy containing these metals. Examples of the oxide include alumina, silica, magnesia, and calcia. Examples of the refractory material include boron nitride and carbon. The crucible 9a may be water-cooled.

The source gas inlet 30 extends from the outside to the inside of the vacuum chamber 22. One end of the source gas inlet 30 is directed to the space between the evaporation source 9 and the substrate 21. The other end of the source gas inlet 30 is connected to a source gas supplier (not shown), such as a gas cylinder and a gas generating apparatus, outside the vacuum chamber 22. When an oxygen gas or a nitrogen gas is fed into the vacuum chamber 22 through the source gas inlet 30, a thin film containing an oxide, nitride, or oxynitride of the material 9b in the crucible 9a can be formed.

During the film formation process, the vacuum pump 34 is used to maintain the inside of the vacuum chamber 22 at a pressure, for example, 1.0×10⁻³ to 1.0×10⁻¹ Pa, suitable for forming a thin film. As the vacuum pump 34, various types of vacuum pumps can be used, such as a rotary pump, an oil diffusion pump, a cryopump, and a turbomolecular pump.

The material supplying unit 42 is used to melt, above the evaporation source 9, a bulk material 32 containing a source material of the thin film to be formed, and to supply the melted material to the evaporation source 9 in the form of droplets 14. In the present embodiment, a silicon material 32 is used as the bulk material 32. The material supplying unit 42 can supply silicon continuously to the evaporation source 9 in accordance with the consumption of the material 9b (a silicon melt) in the crucible 9a without purging the inside of the vacuum chamber 22 with air, etc. Furthermore, the material supplying unit 42 can supply silicon to the evaporation source 9 while allowing the silicon particles coming from the evaporation source 9a to be deposited on the substrate 21. Thereby, long-time continuous film formation can be performed.

It also is possible to stop forming the thin film temporarily to supply silicon to the crucible 9a. That is, it also is possible to perform alternately the process of supplying silicon to the crucible 9a and the process of depositing silicon on the substrate 21. Furthermore, it is conceivable to use a load lock system to transfer the substrate (a glass substrate, for example) to the film forming position 33 and retract this substrate from the film forming position 33.

In the present embodiment, the material supplying unit 42 is composed of a conveyor 10 and the electron gun 15. The conveyor 10 serves to hold the silicon material 32 horizontally as well as to transfer the silicon material 32 above the crucible 9a of the evaporation source 9. The electron gun 15 serves to heat the silicon material 32 that has been transferred above the crucible 9a. In the present embodiment, the electron gun 15 also serves to heat and evaporate the material 9b in the crucible 9a.

The silicon material 32 is transferred above the crucible 9a by the conveyor 10, and is heated and melted with an electron beam 16. The silicon melt generated by the melting falls into the crucible 9a in the form of the droplets 14. Thereby, silicon as the source material of the thin film is supplied to the crucible 9a. Another electron gun for heating the silicon material 32 may be provided in addition to the electron gun for heating the material 9b in the crucible 9a. Moreover, as a means for heating the silicon material 32, a laser irradiation apparatus also can be used instead of or together with the electron gun. In the case of using the electron beam or the laser beam, the fine powder generated by the crushing of the silicon material 32 is electrically charged by the electron beam or the laser beam and is likely to scatter as splashes. Thus, in the case of using the electron beam or the laser beam, it particularly is recommended to use the silicon material 32 that is hardly crushed.

It is desirable that the silicon material 32 have a mass of, for example, 0.5 kg or more, in other words, a sufficient heat capacity. In the silicon material 32 thus provided, an increase in the overall temperature can be suppressed when its tip portion is heated rapidly. In this case, since the tip portion of the silicon material 32 is melted selectively, it is easy to keep the same dropping position. More specifically, it is possible to supply stably the material to the crucible 9a without causing the droplets 14 to fall outside the crucible 9a. The upper limit of the mass of the silicon material 32 is not particularly limited. It is, for example, 10 kg when the size of the thin film manufacturing apparatus 20 is taken into consideration.

In the present embodiment, the silicon material 32 is rod-shaped or columnar. The silicon material 32 in such a shape has a small surface area, and thus the amount of moisture adhered to the surface also is small. Typically, the silicon material 32 has the shape of a rod with a circular cross section. The diameter of the silicon material 32 is not particularly limited. It is, for example, 50 to 100 mm.

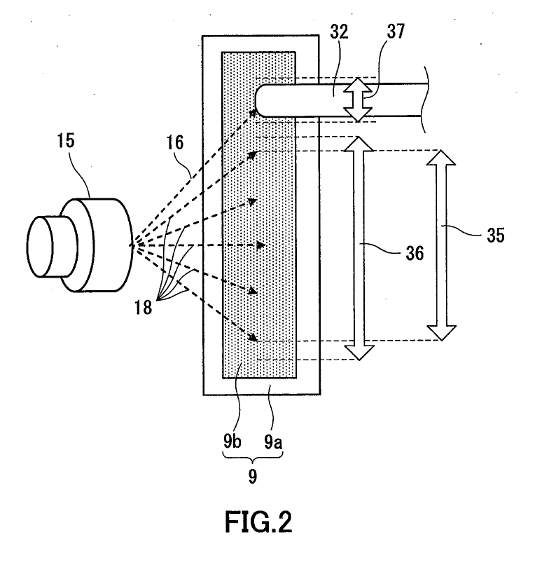

As shown in FIG. 2, the crucible 9a has the rectangular opening wider than an opening width 35 of the opening 31 of the shielding plate 29. The position of the tip portion of the silicon material 32 is determined not to overlap with the opening 31 of the shielding plate 29 when viewed in plane. In order to evaporate the material 9b in the crucible 9a, a scanning zone 36 is irradiated with the electron beam 18. The scanning zone 36 is set to be wider than the opening width 35 of the shielding plate 29 with respect to the longitudinal direction (the width direction) of the crucible 9a. This enhances the uniformity of the widthwise thin film thickness.

For further effectiveness in enhancing the uniformity of the widthwise thin film thickness, both ends of the scanning zone 36 with respect to the width direction are irradiated with the electron beam 18 for a longer time than that spent at other positions.

On the other hand, the irradiation position of the electron beam 16 for melting the silicon material 32 is set to be outside of the scanning zone 36 of the electron beam 18. In other words, the dropping position of the silicon droplets 14 is set to be outside of the scanning zone 36. When the irradiation position of the electron beam 16 and the dropping position of the droplets 14 are set to be outside of the scanning zone 36 of the electron beam 18, it is possible to reduce the influence to the film formation caused by the temperature change in the material 9b (the silicon melt) and the vibration of the liquid surface of the material 9b when the droplets 14 are supplied.

As the silicon material 32, the silicon material 32 including a plurality of pores therein is recommended. When the silicon material 32 has the pores isolated from the outside air, the pores stop cracks spreading even if the cracks occur due to the thermal expansion during the rapid heating, preventing the silicon material 32 from being crushed. In addition, the pores have a function of relaxing the stress caused by the thermal expansion and preventing the crushing. As a result, it is possible to suppress a decrease in the temperature of the material 9b in the crucible 9a due to the fall of a part of the silicon materials 32 in the unmelted state, and to suppress a decrease in the evaporation rate that may occur in association with this temperature decrease. Furthermore, it is possible to suppress splashes (fine powder) from being generated by the crushing, making it possible to prevent the fine powder from being deposited on the substrate 21 and to prevent the substrate 21 from being damaged by the fine powder.

Preferably, the pores of the silicon material 32 have a lower average internal pressure than an atmospheric pressure. In this case, it is possible to reduce the pressure change in the vacuum chamber 22 when the silicon material 32 is melted. This is advantageous in forming a high-quality thin film. More preferably, the pores have an average internal pressure of 0.1 atm or less. When the average internal pressure is kept at 0.1 atm or less, it is possible to prevent a large stress from being generated in the silicon material 32 due to the thermal expansion of the gas in the pores. As a result, it is possible to lower further the possibility of the silicon material 32 being crushed. Moreover, when the average internal pressure of the pores is sufficiently low, it is possible to prevent the gas from bursting out from the pores when the silicon material 32 is melted. Accordingly, it is possible to prevent the silicon melt from scattering, as splashes, directly from the portion being heated with the electron beam 16.

The average internal pressure of the pores can be calculated by the bulk density of the silicon material 32 and the amount of gas released when the material is being melted. Specifically, the average internal pressure can be calculated as follows. First, water is poured into a graduated cylinder and the silicon material 32 is sunk in the water to measure the volume of the silicon material 32. The mass of the silicon material 32 is divided by the volume to obtain the bulk density of the silicon material 32. The total volume of the pores can be calculated by a difference between the bulk density and a true density of silicon (for example, the density of metal silicon having no pores). Subsequently, the silicon material 32 is put into a vacuum chamber and the vacuum chamber is evacuated up to an arbitrary vacuum degree (1.0×10⁻² Pa, for example). The evacuation is stopped, and then the silicon material 32 is heated and melted, and the pressure change in the vacuum chamber is measured. Along with the pressure change measurement, the generated gas is analyzed by a mass spectrograph. The amount of gas released from the silicon material 32 is calculated based on the volumetric capacity of the vacuum chamber and the measured pressure change. The average pressure of the gas, that is, the average internal pressure of the pores can be calculated from the total volume of the pores and the amount of gas released.

If a large amount of gas component adsorbed on the inner wall, etc. of the vacuum chamber is released, the pressure measurement may be performed after the vacuum chamber is once evacuated up to a still higher vacuum degree (1.0×10⁻³ Pa, for example), and a gas (such as a nitrogen gas, an argon gas, and a helium gas) with a known composition is introduced so that the vacuum degree is adjusted to the same vacuum degree as that used for the above-mentioned measurement after the release of the adsorbed gas is stabilized.

The lower limit of the average internal pressure of the pores is not particularly limited. With the after-mentioned casting process under atmospheric pressure, an average internal pressure of about 0.01 atm can be achieved. Of course, a still lower average internal pressure can be achieved with a casting process under vacuum.

As the silicon material 32, a silicon cast produced by a casting process can be used more suitably than a silicon bulk produced by a pulling process. The casting process makes it possible to adjust the dimensions and the average internal pressure of the pores, etc. relatively easily. The silicon cast can be produced by heating and melting metal silicon, pouring the obtained melt into a mold, and cooling the melt. As the metal silicon, it is possible to use metal-grade silicon for metallurgical use with a purity of about 99%. Instead of or together with the metal silicon, high purity silicon, such as scraps of silicon for semiconductors and solar cells, can be used. Furthermore, it is possible that a silicon oxide, such as silica, is melted with a reducing agent to obtain a silicon melt, and pour the melt into a mold.

Typically, the silicon material 32 can be produced by casting the metal silicon at ordinary temperature and pressure (in the air). For example, the metal silicon is put into a fire-resistant crucible, and the metal silicon is heated at 1500 to 1800° C. to be melted. As the fire-resistant crucible, a fire-resistant crucible made of alumina, silica, or a mixture of these can be used. The method for heating the metal silicon is not particularly limited. It is possible to use various heating methods such as a method in which a resistance heater is used, a method in which combustion of hydrogen or methane is utilized, a high frequency induction heating method, and a method in which arc discharge is utilized. Slag, such as silica produced on the surface of the melt due to a reaction of silicon with oxygen in the air, is removed, and then the crucible is tilted to pour the silicon melt into an cast-iron mold and the silicon in the mold is cooled gradually at ordinary temperature. Thus, a silicon cast having pores therein is obtained.

Preferably, the temperature of the silicon melt when it is poured into the mold is 1550 to 1750° C. When such a melt with a relatively high temperature is poured, it takes a relatively long time to solidify the silicon in the mold. When the silicon is solidified over a long time, the gas staying on the mold and the gas melted into the silicon melt appropriately are discharged outside, and thereby the effect of lowering the average internal pressure of the pores can be obtained. Moreover, the slow solidification of the silicon is effective also in reducing the shrinkage distortion of the silicon material 32. The reduced shrinkage distortion lowers further the occurrence rate of crushing when the silicon material 32 is irradiated with the electron beam 16 and heated.

The pouring rate of the silicon melt into the mold is, for example 0.1 to 0.7 kg/sec. Keeping the pouring rate at 0.1 kg/sec or more makes it possible to form a sufficient number of pores in the silicon material 32. Keeping the pouring rate at 0.7 kg/sec or less makes it possible to discharge appropriately the gas staying on the mold and the gas melted into the silicon melt, which is effective in lowering the average internal pressure of the pores.

In order to suppress the generation of slag, the melting and the casting may be performed in an inert atmosphere such as an argon atmosphere, or in a vacuum. It is effective to use a nonoxidative crucible, such as a graphite crucible and a silicon carbide crucible, as the fire-resistant crucible. A combination of these conditions can suppress further the generation of slag.

When silicon is cast in the air or in a vacuum, it is possible to produce the silicon material 32 having a bulk density in a range of, for example, 2.00 to 2.25 g/cm³. The total volume of the pores is in a range of, for example, 5 to 15% as a percentage to the total volume of the silicon material 32. The volumetric shrinkage during the solidification and the oxygen absorption by the partial oxidation of silicon allow the internal pressure of each of the pores to be lower than the pressure in the atmosphere used for the casting. For example, the average internal pressure of the pores can be adjusted to 0.1 atm or less even when the casting is performed in the air.

The average volume of the pores can be measured using an X-ray CT scan image. The average volume of the pores is not particularly limited because there is a case where two or more pores are adjacent to each other to form a larger pore. However, adjusting the average volume of the pores in a range of 1 to 20 mm³ sufficiently is effective in stopping cracks spreading, and sufficiently can prevent gas from bursting out from the pores and generating bubbles at the portion irradiated with the electron beam 16 when the silicon material 32 is melted.

The pores may be distributed uniformly throughout the entire silicon material 32, or may be distributed radially from a central part of the silicon material 32. The radially-distributed pores make it easy to keep the strength of the silicon material 32 high, thereby lowering further the possibility of the silicon material 32 being crushed due to the thermal expansion of the gas in the pores. In addition, when the pores are distributed radially, the distances among the pores are ensured properly, thereby preventing the pores from forming larger pores by communicating with each other. In this case, it is possible to prevent splash-inducing bubbles from being generated at the portion being heated with the electron beam 16.

During the casting, oxygen in the pores is absorbed into the surrounding silicon. Thus, the partial pressure of an oxygen gas in the pores is lowered gradually as the solidification of silicon proceeds. Accordingly, the partial pressure of an inert gas containing nitrogen, argon, or a mixed gas of these increases. The reaction rate between silicon and oxygen is known to increase as the temperature rises, according to the Arrhenius equation. During the casting, the silicon cast is cooled continuously from the outside thereof mainly by the heat transfer to the mold and the heat radiation to the outside of the mold. Thus, oxygen in the pores is more likely to react with silicon at a high-temperature portion in the inner circumferential surfaces of the pores, that is, at a portion closer to a center of the silicon cast. That is, silica is produced locally on the inner circumferential surfaces of the pores at a central part of the silicon cast. In this case, it is easy to remove silica from the crucible 9a because the silica appears as a relatively large slag when the silicon material 32 is melted. This also contributes to the formation of a thin film containing less impurities and having a uniform composition.

Generally, metal silicon is required to have a uniform composition when used as a material for producing high purity silicon for semiconductors and solar cells. Thus, oxygen is present uniformly in commercially-available metal silicon bulks. When oxygen is present uniformly in a metal silicon bulk, fine silica particles (with a diameter of 0.1 mm, for example) are precipitated here and there on the metal silicon bulk when it is reheated. In this case, it is extremely difficult to detect the presence of silica, and the presence is not recognized until slag appears in the melt when the metal silicon is melted. Since silicon must be refined in the manufacturing processes of solar cells and semiconductors, silica hardly makes such a problem. However, in the case where commercially-available metal silicon is used as a material for vapor deposition, even a small amount of fine silica powder covers the surface of the melt, which produces a problem. More specifically, the fine silica powder spreads like an oil slick, making it difficult for silicon to be evaporated.

In contrast, in the case where a silicon cast is produced using metal silicon as a source material, the temperature distribution in the silicon in the mold becomes nonuniform, and thus silica is more likely to be segregated at around the center of the mold. More specifically, silica tends to be produced on the inner circumferential surfaces of the pores at the central part of the silicon cast, in the form of slightly larger particles (with a diameter of 0.5 to 1 mm, for example). In the case where silica is produced in the form of particles that are large in size to some extent, the silica can be detected also by X-ray CT scan, and also, the silica can be filtered out using a filtering material, such as carbon wool, even when it appears on the surface of the melt during vapor deposition. Specifically, when carbon wool is provided near an end part in the crucible 9a, slag containing silica flows to the carbon wool by the convection of the melt and is caught and filtered out by the carbon wool. As a result, a thin film containing less impurities and having a uniform composition can be formed. Moreover, it also is possible to suppress the variation in the evaporation rate caused by the floating silica on the melt.

If the partial pressure of the oxygen gas in the pores is high, oxygen is released into the vacuum when the silicon material 32 is melted, which may contribute to the variation in the composition of the thin film. Also from this viewpoint, it is desirable that the partial pressure of the oxygen gas in the pores be sufficiently reduced. In the silicon material 32 of the present embodiment, the pores have, on average, a partial pressure of an oxygen gas of 10% or less with respect to a total pressure. Moreover, the pores have, on average, a partial pressure of an inert gas of 90% or more with respect to the total pressure. The inert gas contains nitrogen, argon, or a mixed gas of these. The above-mentioned casting process makes it possible to reduce sufficiently the average internal pressure and the partial pressure of the oxygen gas by adjusting the pouring rate of the melt into the mold, the temperature of the melt being poured, etc. The lower limit of the partial pressure of the oxygen gas is not particularly limited. It can be, for example, 3% with respect to the total pressure. The upper limit of the inert gas partial pressure is not particularly limited, either. It can be, for example, 15% with respect to the total pressure. When the casting is performed in the air, the nitrogen gas mainly remains in the pores. When the casting is performed in an inert gas or in a vacuum, the partial pressure of the oxygen gas in the pores can be reduced to around 0%.

The partial pressure of the gas in the pores can be measured as follows. First, a small specimen, with a size of about 1 cm³, to be used for the partial pressure measurement is cut out from the silicon material 32. The small specimen for the partial pressure measurement is compressed and crushed in a vacuum chamber decompressed to about 1×10⁻² Pa (with a volumetric capacity of about 100 cm³), and the composition of the generated gas is measured with a mass spectrograph. The partial pressure of each component of the gas can be calculated from this composition.

When producing the silicon material 32 by the casting process, the amount of gas adsorbed on the mold may be adjusted in advance, as well as a small amount of gas may be blown into the silicon melt. The method for manufacturing the silicon material 32 is not limited to the casting process. The present invention is not limited by the method for manufacturing the silicon material 32, either.

### EXAMPLES

The following tests were conducted in order to confirm the effects of the present invention.

A plurality of the rod-shaped silicon materials 32 were produced in the air by the casting process described above. First, metal silicon was heated at 1750° C. and melted in a crucible. The obtained silicon melt was poured into a cast-iron mold and cooled gradually at room temperature. As a result, the rod-shaped silicon material 32 with a length of 300 mm and a diameter of 50 mm was obtained. A plurality of the silicon materials 32 (Samples 1 to 11) with the same shape and size as mentioned above were produced while changing the pouring rate in a range of 0.1 to 2.2 kg/sec. In addition, a plurality of the silicon materials 32 were produced at the same pouring rates as these rates, respectively. That is, a plurality of the silicon materials 32 were prepared for each of Samples 1 to 11.

Still additionally, a plurality of the silicon materials 32 were produced as Sample 12 by the following sintering process. First, 10-mesh-size silicon powder (with an average particle diameter of about 380 μm) was put into a molybdenum mold with a length of 400 mm and a diameter of 50 mm. Subsequently, the silicon particles were compressed by applying a load of 2.0×10⁵ kgf along the longitudinal direction of the molybdenum mold. Next, the molybdenum mold was put into a high temperature furnace and the atmosphere in the furnace was replaced with an argon atmosphere at atmospheric pressure, and then was heated to 1450° C. It was kept at 1450° C. for 60 minutes, and then the power was turned off and the sintered silicon product was cooled gradually in the molybdenum mold. In this way, the silicon materials 32 as Sample 12 were obtained.

Still additionally, a dense silicon material (Sample 13) also was prepared as a comparative example. The dense silicon material was produced as follows. First, 1.3 kg of metal silicon was put into a graphite crucible with a length of 450 mm and a diameter of 50 mm. Next, the graphite crucible was put into a vacuum furnace (1.0×10⁻¹ Pa), the temperature in the vacuum furnace was raised to 1650° C., and kept for 3 hours for degassing. Subsequently, the graphite crucible was cooled from 1650 to 1300° C. over 20 hours. It was cooled further from 1300° C. to room temperature over 4 hours. Finally, the crucible was broken. Thus, the dense silicon material with a length of 300 mm and a diameter of 50 mm was obtained. A plurality of the dense silicon material were prepared as in the case of the other silicon materials.

(Average Volume of Pores)

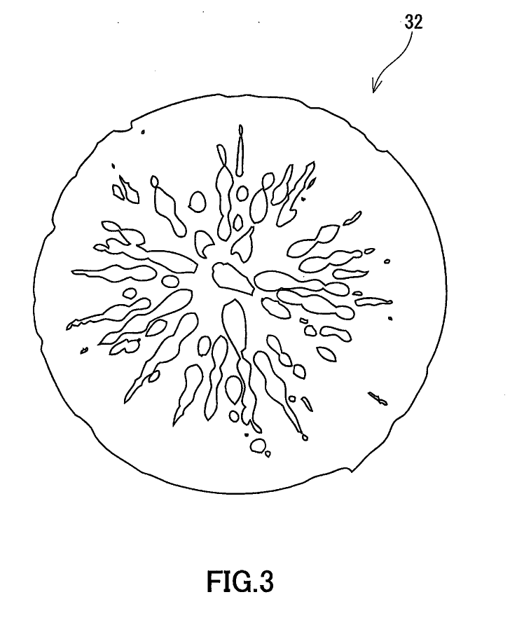

Next, the internal structure of each of the samples was observed by X-ray CT scan, and the average volume of the pores therein was estimated. FIG. 3 shows a cross sectional image of one of the silicon materials 32 produced as Sample 5, captured by X-ray CT scan. As shown in FIG. 3, the pores were formed radially from a central part of the sample.

The “average volume of the pores” was calculated as follows. For example, the average volume of the pores in each of 20 silicon materials 32 produced as

Sample 1 was estimated, and the average of these estimated values was determined as the “average volume of the pores” in Sample 1. That is, the “average volume” shown in Table 1 is a value obtained by averaging further the average values of the silicon materials produced under the same conditions. This makes it possible to calculate the “average volume” more accurately. This applies also to the “average internal pressure”, “average nitrogen partial pressure”, and “number of splashes generated” described below.

(Average Internal Pressure and Average Nitrogen Partial Pressure)

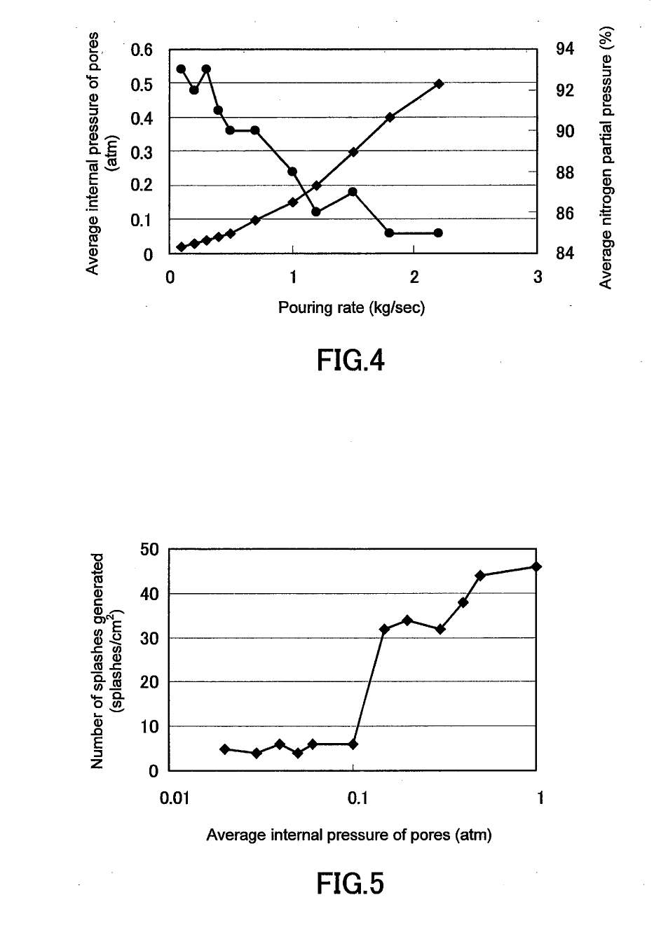

Next, a 1 cm³ small specimen to be used for partial pressure measurement was cut out from each of the samples with a diamond cutter, at a portion in which the pores detected by X-ray CT scan were most unlikely to be collapsed. The average internal pressure of the pores and the average nitrogen partial pressure in the pores were measured by the method described above, using these small specimens for partial pressure measurement. Table 1 shows the results thereof. FIG. 4 illustrates the values shown in Table 1 in graph form. In FIG. 4, the diamond-shaped dots indicate the pouring rate data, and the circular dots indicate the average nitrogen partial pressure data.

TABLE 1

| | Pouring | Average volume | Average internal | Average nitrogen | Number of | Occurrence rate |
|---|---|---|---|---|---|---|
| | rate | of pores | pressure | partial pressure | splashes generated | of crushing |
| | (kg/sec) | (mm³) | (atm) | (%) | (splashes/cm²) | (%) |
| Sample 1 | 0.1 | 0.8 | 0.02 | 93 | 5 | 10 |
| Sample 2 | 0.2 | 3 | 0.03 | 92 | 4 | 15 |
| Sample 3 | 0.3 | 3 | 0.04 | 93 | 6 | 5 |
| Sample 4 | 0.4 | 8 | 0.05 | 91 | 4 | 5 |
| Sample 5 | 0.5 | 10 | 0.06 | 90 | 6 | 10 |
| Sample 6 | 0.7 | 18 | 0.1 | 90 | 6 | 15 |
| Sample 7 | 1 | 22 | 0.15 | 88 | 32 | 40 |
| Sample 8 | 1.2 | 28 | 0.2 | 86 | 34 | 30 |
| Sample 9 | 1.5 | 40 | 0.3 | 87 | 32 | 45 |
| Sample 10 | 1.8 | 38 | 0.4 | 85 | 38 | 40 |
| Sample 11 | 2.2 | 52 | 0.5 | 85 | 44 | 40 |
| Sample 12 | — | 55 | 1 | 79 | 46 | 50 |
| Sample 13 | — | 0 | 0 | 0 | 38 | 60 |
| (dense material) | | | | | | |

As shown in Table 1 and FIG. 4, the average internal pressure of the pores was almost proportional to the pouring rate. The average nitrogen partial pressure in the pores was almost inversely proportional to the pouring rate. Samples 1 to 6 each had an average nitrogen partial pressure of 90% or more, in other words, an average oxygen partial pressure of 10% or less.

(Number of Splashes Generated)

Next, a thin film was formed on the substrate 21 with the thin film manufacturing apparatus 20 described with reference to FIG. 1. As the silicon material 32, each of Samples 1 to 13 was set in the conveyor 10 of the material supplying unit 42 shown in FIG. 1. Also, the silicon melt thereof was held in the crucible 9a in advance. The driving speed of the take-up roller 27 was adjusted so that a thin film can be formed at a rate of 200 to 500 nm/sec. A copper foil with a thickness of 35 μm was used as the substrate 21. The pressure in the vacuum chamber 22 was 1×10⁻² Pa. While the silicon material 32 was irradiated with the electron beam 16 so that the silicon melt was dropped into the crucible 9a, the silicon melt 9b in the crucible 9a also was irradiated with the electron beam 18 to evaporate silicon. Thereby, silicon particles were deposited on the substrate 21. The intensity of the electron beam 16 was set to 1.5 kW/cm².

After the film had been formed, the substrate 21 was recovered from the take-up roller 27, and an arbitrary region of the substrate 21 was observed with a magnifying glass (at a magnification of 20). Then, the number of particle deposits observed was counted as “splashes.” Table 1 shows the results thereof. FIG. 5 illustrates the values shown in Table 1 in graph form. As shown in FIG. 5, when the average internal pressure of the pores exceeded 0.1 atm, the number of the splashes generated increased sharply.

(Occurrence Rate of Crushing)

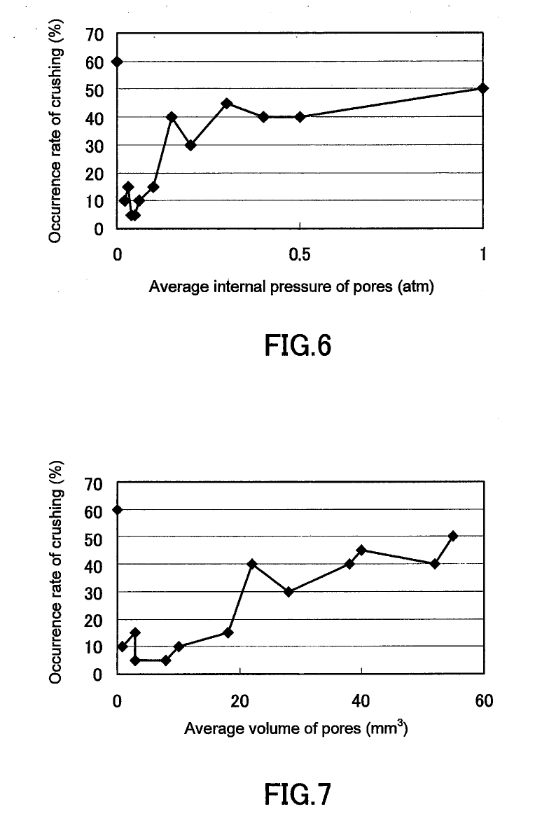

Next, the samples each were checked for the occurrence rate of crushing in the case where they were irradiated with the electron beam 16 and melted by the following procedure. Specifically, each of the 20 samples produced at the same pouring rate was irradiated with the electron beam 16 for 5 minutes in a vacuum, and the presence of crushing was judged visually. During the irradiation with the electron beam 16, each of the samples was moved forward at a speed of 50 mm/min. The intensity of the electron beam 16 was 1.3 kW/cm², and the vacuum degree was 1×10⁻² Pa. It was judged that “crushing occurred” when an unmelted fragment with a diameter of about 5 mm or more was found fallen in the vacuum chamber after 5 minutes of the electron beam irradiation. Table 1 shows the results thereof. FIGS. 6 and 7 each illustrate the values shown in Table 1 in graph form.

As shown in FIG. 6 and FIG. 7, the dense silicon material (Sample 13) had the highest occurrence rate of crushing. All of the silicon materials having the pores (Samples 1 to 12) had occurrence rates of crushing lower than that of the dense silicon material. Particularly, their occurrence rates of crushing were low when the average internal pressure of the pores was 0.1 atm or less, or when the average volume of the pores was in a range of 1 to 20 mm³.

### INDUSTRIAL APPLICABILITY

The present invention can be applied to the manufacture of elongated electrode plates of energy storage devices. As the substrate 21, a metal foil, such as a copper foil and a copper alloy foil, is used. The material 9b (silicon) in the crucible 9a is evaporated using the electron beam 18, so that a silicon thin film is formed on the substrate 21 serving as a negative electrode collector. Introducing a small amount of oxygen gas into the vacuum chamber 22 makes it possible to form a silicon thin film containing silicon and a silicon oxide on the substrate 21. Since silicon is capable of occluding and releasing lithium therein and therefrom, the substrate 21 on which the silicon thin film has been formed can be utilized as a negative electrode of a lithium ion secondary battery.

The present invention can be applied not only to electrode plates of energy storage devices and magnetic tapes but also to the manufacture of thin films containing at least one of silicon and a silicon oxide as a main component, such as capacitors, various sensors, solar cells, various optical films, moisture-proof films, and conductive films. The present invention is effective particularly when films are formed for electrode plates of energy storage devices, which require long-time film formation and formation of relatively thick films.

1. A method for manufacturing a thin film, comprising the steps of:
depositing particles coming from an evaporation source on a substrate at a predetermined film forming position in a vacuum so as to form the thin film on the substrate; and
melting a bulk material containing a source material of the thin film above the evaporation source and supplying the melted material to the evaporation source in the form of droplets,
wherein a silicon material including a plurality of pores therein is used as the bulk material.

2. The method for manufacturing the thin film according to claim 1, wherein the pores have a lower average internal pressure than an atmospheric pressure.

3. The method for manufacturing the thin film according to claim 1, wherein the average internal pressure is 0.1 atm or less.

4. The method for manufacturing the thin film according to claim 1, wherein the pores have, on average, a partial pressure of an oxygen gas of 10% or less with respect to a total pressure.

5. The method for manufacturing the thin film according to claim 1, wherein the pores have, on average, a partial pressure of an inert gas of 90% or more with respect to a total pressure, the inert gas containing nitrogen, argon, or a mixed gas of these.

6. The method for manufacturing the thin film according to claim 1, wherein the pores have an average volume in a range of 1 to 20 mm³.

7. The method for manufacturing the thin film according to claim 1, wherein the silicon material is produced by a casting process.

8. The method for manufacturing the thin film according to claim 1, wherein:
the substrate is an elongated substrate;
the depositing step includes transferring the elongated substrate fed from a feed roller to a take-up roller through the predetermined film forming position; and
while the depositing step is performed, the supplying step is performed.

9. The method for manufacturing the thin film according to claim 1, wherein the bulk material is melted by irradiation with an electron beam or a laser beam.

10. A method for manufacturing a negative electrode for a lithium ion secondary battery, comprising the step of depositing silicon as a negative electrode active material capable of occluding and releasing lithium therein and therefrom, on the substrate serving as a negative electrode collector, by the method for manufacturing the thin film according to claim 1.

11. A silicon material as a bulk material, including a plurality of pores therein,
the silicon material being used in a method for manufacturing a thin film, the method comprising the steps of;
depositing particles coming from an evaporation source on a substrate at a predetermined film forming position in a vacuum so as to form the thin film on the substrate; and
melting the bulk material containing a source material of the thin film above the evaporation source and supplying the melted material to the evaporation source in the form of droplets.

12. The silicon material according to claim 11, wherein the pores have a lower average internal pressure than an atmospheric pressure.

13. The silicon material according to claim 12, wherein the average internal pressure is 0.1 atm or less.

14. The silicon material according to claim 11, wherein the pores have, on average, a partial pressure of an oxygen gas of 10% or less with respect to a total pressure.

15. The silicon material according to claim 11, wherein the pores have, on average, a partial pressure of an inert gas of 90% or more with respect to a total pressure, the inert gas containing nitrogen, argon, or a mixed gas of these.

16. The silicon material according to claim 11, wherein the pores have an average volume in a range of 1 to 20 mm³.

17. The silicon material according to claim 11, wherein the silicon material is produced by a casting process.
